(19) United States
(12) Patent Application Publication
(10) Pub. No.: US 2008/0224190 A1
(43) Pub. Date: Sep. 18, 2008

(54) IMAGE SENSOR AND METHOD OF FABRICATING THE SAME

(76) Inventors: Jong-Min Lee, Cheonan-si (KR); Jong-Cheol Shin, Suwon-si (KR); Doo-Cheol Park, Suwon-si (KR); Jeong-Hoon Koo, Cheonan-si (KR); Hee-Yong Lim, Cheonan-si (KR)

Correspondence Address: F. CHAU & ASSOCIATES, LLC, 130 WOODBURY ROAD, WOODBURY, NY, 11797, US

(21) Appl. No.: 12/046,965

(22) Filed: Mar. 12, 2008

(30) Foreign Application Priority Data
Mar. 16, 2007 (KR) 10-2007-0026276

(51) Int. Cl. H01L 31/113; H01L 21/00

(52) U.S. Cl. 257/292; 438/69; 257/E27.133

(57) ABSTRACT

An image sensor with sufficient photoelectric conversion capacity and enhanced reliability and a method of fabricating the same, in which the image sensor includes a bare substrate; an epitaxial layer disposed on the bare substrate and including a first impurity distribution region of a first conductivity type, which is formed on the bare substrate, and a second impurity distribution region of a second conductivity type, which is formed on the first impurity distribution region; and a charge collection well formed within the epitaxial layer and at least partially doped with third impurities of the second conductivity type, wherein the charge collection well occupies the first impurity distribution region and the second impurity distribution region and represents the second conductivity type as a whole.

This application claims priority from Korean Patent Application No. 10-2007-026276 filed on Mar. 16, 2007 in the Korean Intellectual Property Office, the disclosure of which is incorporated herein by reference in its entirety.

### BACKGROUND OF THE INVENTION

1. Technical Field

The present disclosure relates to an image sensor and a method of fabricating the same and, more particularly, to an image sensor with sufficient photoelectric conversion capacity and enhanced reliability and a method of fabricating the same.

2. Discussion of Related Art

With recent advancements in the computer and communication industries, the demands for image sensors with enhanced performance are increasing in various fields such as digital cameras, camcorders, personal communication systems, game devices, security cameras, and micro-cameras for medical use.

Metal oxide semiconductor (MOS) image sensors can be driven using a simple driving method and can be implemented using various scanning methods. In addition, because signal processing circuits can be integrated onto a single chip, smaller products can be manufactured. Also, because compatible MOS processing technology is used, manufacturing costs can be reduced. Due to their very low power consumption, MOS image sensors can be utilized in products with limited battery capacity. In other words, technological development accompanied by the achievement of high resolution is sharply increasing the use of MOS image sensors.

If the integration density of pixels is increased according to an enhanced resolution, however, an area of a photoelectric converter in each unit pixel is reduced, thereby deteriorating the sensitivity and decreasing an amount of saturation signals. A method of increasing the depth of the photoelectric converter has been suggested in order to provide sufficient photoelectric conversion capacity using the same area. To this end, however, the method requires excessive ion implantation energy. Consequently, peripheral structures can be attacked, and impurity ions cannot be implanted at an accurate concentration. Also, while a red sensitivity increases excessively, there is no significant improvement in sensitivity to green, which is a weak signal. Furthermore, crosstalk between pixels can occur.

### SUMMARY OF THE INVENTION

Exemplary embodiments of the present invention provide an image sensor with sufficient photoelectric conversion capacity and enhanced reliability.

Exemplary embodiments of the present invention also provide a method of fabricating an image sensor with sufficient photoelectric conversion capacity and enhanced reliability.

Exemplary embodiments of the present invention also provide an epitaxial substrate used to fabricate an image sensor with sufficient photoelectric conversion capacity and enhanced reliability.

The exemplary embodiments of the present invention are not restricted to those set forth herein. The above and other objectives of the present invention will become more apparent to one of ordinary skill in the art to which the present invention pertains by referencing the detailed description given below.

According to an exemplary embodiment of the present invention, there is provided an image sensor that includes a bare substrate; an epitaxial layer disposed on the bare substrate and including a first impurity distribution region of a first conductivity type, which is formed on the bare substrate, and a second impurity distribution region of a second conductivity type, which is formed on the first impurity distribution region; and a charge collection well formed within the epitaxial layer and at least partially doped with third impurities of the second conductivity type, wherein the charge collection well occupies the first impurity distribution region and the second impurity distribution region and represents the second conductivity type as a whole.

According to an exemplary embodiment of the present invention, there is provided a method of fabricating an image sensor that includes providing an epitaxial substrate for an image sensor, the epitaxial substrate including a bare substrate and an epitaxial layer, which is disposed on the bare substrate, and comprises a first impurity distribution region of a first conductivity type, which is formed on the bare substrate, and a second impurity distribution region of a second conductivity type, which is formed on the first impurity distribution region; and forming a charge collection well, which is at least partially ion-doped with third impurities of the second conductivity type, within the epitaxial layer, wherein the charge collection well occupies the first impurity distribution region and the second impurity distribution region and represents the second conductivity type as a whole.

In an exemplary embodiment of the present invention, there is provided an epitaxial substrate for an image sensor. The epitaxial substrate includes a bare substrate; and an epitaxial layer disposed on the bare substrate and including a first impurity distribution region of a first conductivity type, which is formed on the bare substrate, and a second impurity distribution region of a second conductivity type which is formed on the first impurity distribution region.

### BRIEF DESCRIPTION OF THE DRAWINGS

Exemplary embodiments of the present invention will be understood in more detail from the following descriptions taken in conjunction with the attached drawings, in which:

FIG. 1 is a block diagram of an image sensor according to an exemplary embodiment of the present invention;

FIG. 2 is an equivalent circuit diagram of a unit pixel of an image sensor according to an exemplary embodiment of the present invention;

FIG. 3 is a schematic layout of the unit pixel of FIG. 2;

FIG. 4 is a cross-sectional view of the unit pixel taken along a line IV-IV′ of FIG. 3.

FIG. 5 is a cross-sectional view of an image sensor according to an exemplary embodiment of the present invention

FIG. 6 is a cross-sectional view of an image sensor according to an exemplary embodiment of the present invention

FIG. 7 is a cross-sectional view of an image sensor according to an exemplary embodiment of the present invention;

FIG. 8 is a cross-sectional view of an image sensor for explaining various examples of device isolation according to an exemplary embodiment of the present invention;

FIGS. 9 and 11 through 16 are cross-sectional views for explaining a method of fabricating an image sensor according to an exemplary embodiment of the present invention;

FIG. 10 is a schematic graph of a value representing the relative concentration of impurities doped into each region of an epitaxial substrate;

FIG. 17 is a cross-sectional view of an epitaxial substrate applied to fabricate the image sensor of FIG. 6;

FIG. 18 is a cross-sectional view of an epitaxial substrate applied to fabricate the image sensor of FIG. 7; and

FIG. 19 is a schematic diagram illustrating a processor-based system including a complementary metal oxide semiconductor (CMOS) image sensor according to an exemplary embodiment of the present invention.

### DETAILED DESCRIPTION OF EXEMPLARY EMBODIMENTS

Exemplary embodiments of the present invention will now be described more fully with reference to the accompanying drawings, in which exemplary embodiments of the invention are shown. The invention may, however, be embodied in many different forms and should not be construed as being limited to the exemplary embodiments set forth herein; rather, these exemplary embodiments are provided so that this disclosure will be thorough and complete, and will fully convey the concept of the invention to those of ordinary skill in the art.

In some exemplary embodiments, well-known processing processes, well-known structures, and well-known technologies will not be specifically described in detail in order to avoid an ambiguous interpretation of the present invention.

Image sensors according to exemplary embodiments of the present invention include charge coupled device (CCD) image sensors and complementary metal oxide semiconductor (CMOS) image sensors. CCD image sensors have less noise and provide better image quality than CMOS image sensors. Because CCD image sensors require high voltages, however, their processing costs are high. On the other hand, CMOS image sensors can be driven using a simple driving method and can be implemented using various scanning methods. In addition, because signal processing circuits can be integrated onto a single chip, smaller products can be manufactured. Also, because compatible CMOS processing technology is used, manufacturing costs can be reduced. Due to their very low power consumption, CMOS image sensors can be utilized in products with limited battery capacity. In this regard, CMOS image sensors will hereinafter be described as image sensors according to exemplary embodiments of the present invention, however, it should be understood that the technical spirit of the present invention can also be applied to CCD image sensors.

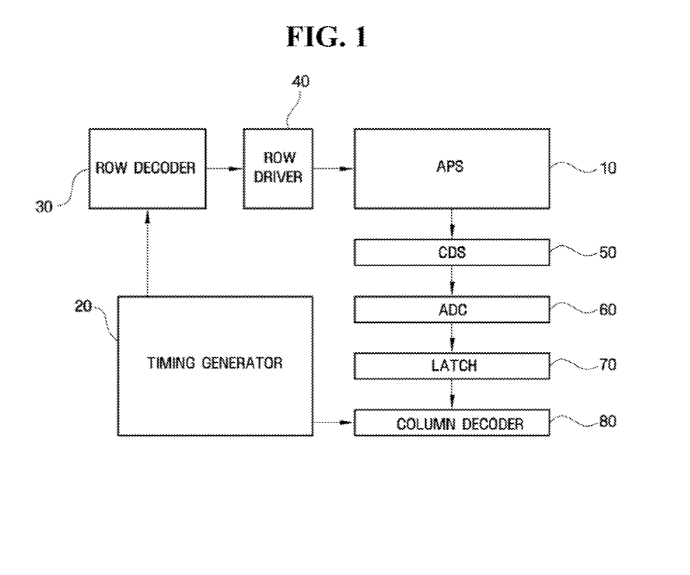

FIG. 1 is a block diagram of an image sensor according to an exemplary embodiment of the present invention.

Referring to FIG. 1, the image sensor according to an exemplary embodiment, of the present invention includes an active pixel sensor (APS) array 10 including a photoelectric converter (not shown), a timing generator 20, a row decoder 30, a row driver 40, a correlated double sampler (CDS) 50, an analog-to-digital converter (ADC) 60, a latch 70, and a column decoder 80.

The APS array 10 includes rows and columns of pixels. Each pixel receives an optical signal and converts the optical signal into an electrical signal. The APS array 10 is driven by a plurality of driving signals, such as a pixel selection signal, a reset signal and a charge transfer signal, transmitted from the row driver 40. In addition, the APS array 10 transmits the electrical signal to the CDS 50 via a vertical signal line.

The timing generator 20 provides a timing signal and a control signal to the row decoder 30 and the column decoder 80.

The row driver 40 provides a plurality of driving signals for driving a plurality of unit pixels to the APS array 10 according to the decoding result of the row decoder 30. For example, if the unit pixels are arranged in a matrix form, the row driver 40 may provide a driving signal to each row of unit pixels.

The CDS 50 receives the electrical signal from the APS array 10 via the vertical signal line and holds and samples the received electrical signal. That is, the CDS 50 doubly samples a specified noise level and a signal level corresponding to the electrical signal and outputs a difference level corresponding to the difference between the noise level and the signal level.

The ADC 60 converts an analog signal corresponding to the difference level into a digital signal and outputs the digital signal.

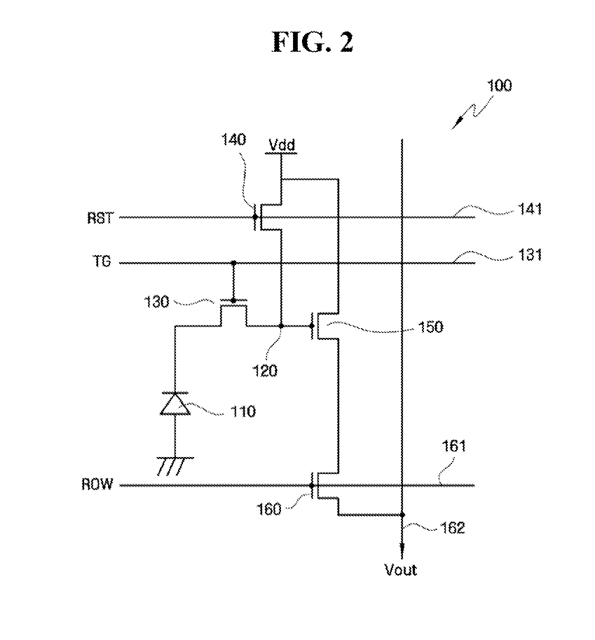

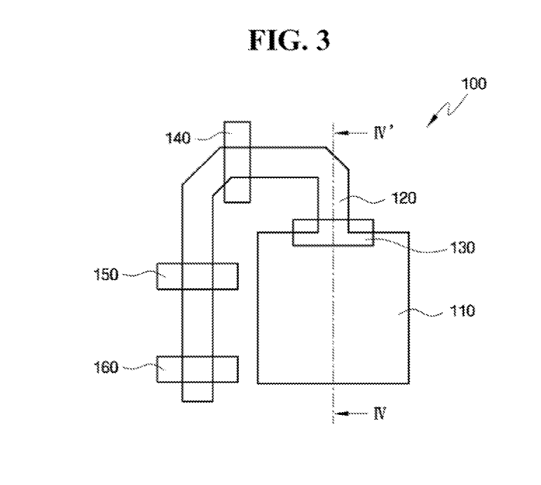

FIG. 2 is an equivalent circuit diagram of a unit pixel 100 of an image sensor according to an exemplary embodiment of the present invention. FIG. 3 is a schematic layout of the unit pixel 100 of FIG. 2.

Referring to FIGS. 2 and 3, the unit pixel 100 includes a photoelectric converter 110, a charge detector shown as a node 120, a charge transmitter 130, a resetter 140, an amplifier 150, and a selector 160. The unit pixel 100 may include four transistors, as illustrated in FIG. 2, however, this is just an example, and each unit pixel may include three or five transistors. That is, the number of transistors can be increased or reduced when necessary.

The photoelectric converter 100 absorbs incident light and accumulates electric charges corresponding to the amount of the incident light. The photoelectric converter 100 may include a photodiode, a phototransistor, a photogate, a pinned photodiode, or a combination of the same.

The charge detector shown as a node 120 is composed of, for example, a floating diffusion (FD) region and receives the accumulated electric charges from the photoelectric converter 110. Because the charge detector 120 has a parasitic capacitance, it can cumulatively store the electric charges. The charge detector shown as a node 120 is electrically connected to a gate of the amplifier 150 and, thus, controls the amplifier 150.

The charge transmitter 130 transfers the electric charges from the photoelectric converter 110 to the charge detector node 120. The charge transmitter 130 may include one transistor (a transfer transistor), and a gate terminal of the transfer transistor is coupled to a charge transfer signal TG on line 131. In addition, source and drain terminals of the transfer transistor 130 are coupled to the photoelectric converter 100 and the charge detector node 120, respectively.

The resetter 140 periodically resets the charge detector shown as a node 120. A source terminal of the resetter 140 is connected to the charge detector 120, and a drain terminal thereof is connected to Vdd. The resetter 140 is driven by a reset signal RST on line 141.

The amplifier 150 functions as a source follower buffer amplifier in conjunction with a constant current source (not shown) located outside the unit pixel 100. The amplifier 150 outputs a voltage, which varies according to a voltage of the charge detector shown as a node 120, to a vertical signal line 162. A source terminal of the amplifier 150 is connected to a drain terminal of the selector 160, and a drain terminal of the amplifier 150 is connected to Vdd.

The selector 160 selects unit pixels to be read in units of rows. The selector 160 is driven by a selection signal ROW on line 161, and a source terminal of the selector 160 is connected to the vertical signal line 162.

Driving signal lines 131, 141 and 161 of the charge transmitter 130, the resetter 140 and the selector 160, respectively, extend in a row direction so that unit pixels in the same row can be driven simultaneously.

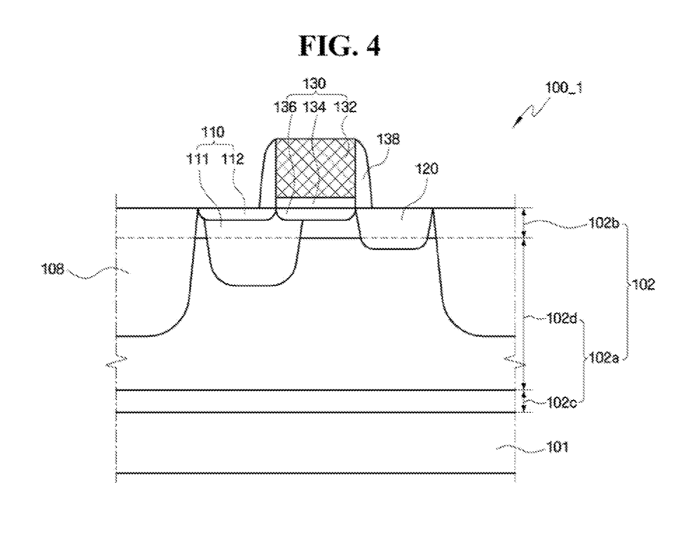

A cross-sectional structure of the unit pixel 100 described above will be described further with reference to FIG. 4. FIG. 4 is a cross-sectional view of the unit pixel 100 taken along a line IV-IV′ of FIG. 3.

Referring to FIG. 4, a unit pixel 100₁₃ 1 of the image sensor according to the exemplary embodiment includes a bare substrate 101, an epitaxial layer 102, the photoelectric converter 110, a transfer gate electrode 132, and the charge detector 120.

The bare substrate 101 may be a semiconductor substrate made of Si, Ge, SiGe, GaP, GaAs, SiC, SiGeC, InAs, InP, or a selective combination of the same. In addition, the bare substrate 101 may be a substrate of a first conductivity type, for example, a P type, or a second conductivity type, for example, an N type. In this exemplary embodiment, a substrate of the first conductivity type (the P type) may be heavily doped with impurities of the first conductivity type (the P type) at a concentration of 1×10¹⁴ atom/cm³ to approximately 1×10²² atom/cm³ and may be applied as the bare substrate 101.

The epitaxial layer 102 is formed on the bare substrate 101 by epitaxially growing, for example, silicon on a whole surface of the bare substrate 101. The epitaxial layer 102 may be divided into at least two distribution regions according to conductivity types of impurities that are distributed therein. In FIG. 4, the epitaxial layer 102 includes a first impurity distribution region 102a in which first impurities of the first conductivity type (the P type) are distributed and a second impurity distribution region 102b in which second impurities of the second conductivity type (the N type) are distributed. The second impurity distribution region 102b is disposed on the first impurity distribution region 102a. The first impurities of the P type may be boron (B) or indium (In), and the second impurities of the N type may be phosphorous (P) or arsenic (As).

As used herein, the term “impurity distribution region” denotes a region where there is at least a predetermined probability of detecting specified impurities. In this case, however, the specified impurities do not necessarily predominate in the region. For example, even if third impurities are doped into a first impurity distribution region and the concentration of the third impurities is higher than that of the first impurities in the first impurity distribution region, the first impurity distribution region may still be referred to as a first impurity distribution region as long as there is a predetermined possibility of detecting the first impurities in the first impurity distribution region. From this point of view, when both of the first and second impurities are distributed in a specified region, the region may be the first impurity distribution region as well as the second impurity distribution region. Thus, the first and second impurity distribution regions may partially overlap each other.

The probability of detecting the specified impurities is determined by the concentration of the specified impurities in the region. That is, if the concentration of the specified impurities increases, the probability of detecting the specified impurities is also increased. If a region where there is an excessively low probability of detecting specified impurities and a region where the concentration of the specified impurities is excessively low are all referred to as specified impurity distribution regions, an area in which different impurity distribution regions overlap may become too wide. In this case, it is difficult to set boundaries between the impurity distribution regions. For this reason, it is inappropriate to refer to such regions as “specified impurity distribution regions.” In order to make such a standard clear, a region may be referred to as a specified impurity distribution region only when there is “at least a predetermined probability” of detecting specified impurities in the region. The predetermined probability may be obtained only when the concentration of the specified impurities in the region is approximately 1×10¹¹ atom/cm³ or greater.

From this point of view, the first impurity distribution region 102a may be where the concentration of the first impurities is at least approximately 1×10¹¹ atom/cm³, and the second impurity distribution region 102b may be where the concentration of the second impurity distribution region 102b is at least approximately 1×10¹¹ atom/cm³. Based on this premise in relation to concentration conditions, various concentrations for enhancing device characteristics are selected for the first and second impurity distribution regions 102a and 102b, respectively.

The first impurity distribution region 102a may be subdivided into a heavily doped region 102c and a lightly doped region 102d.

The heavily doped region 102c is disposed at the bottom of the epitaxial layer 102. That is, the heavily doped region 102c is disposed immediately on the bare substrate 101. The heavily doped region 102c may be doped with the first impurities at a concentration of approximately 1×10¹⁴ atom/cm³ to approximately 1×10¹⁹ atom/cm³. The heavily doped region 102c may be formed to a thickness of approximately 1 to 5 μm and provides a plurality of holes that prevent electric charges generated in the bare substrate 101 thereunder from flowing into a charge collection well 111, so that the electric charges can be recombined with the holes. Therefore, crosstalk between pixels due to the random drift of the electric charges is reduced. More specifically, if a lightly doped substrate of the first conductivity type (the P type) or the second conductivity type (the N type) is applied as the bare substrate 101, the heavily doped region 102c may function as a deep well.

The heavily doped region 102c also defines a region that can collect electric charge data according to photoelectric conversion. That is, electric charges, which are collected as data, are limited to those generated in a region of the epitaxial layer 102 above a top surface of the heavily doped region 102c. Thus, photoelectric conversion efficiency is proportional to the distance between a surface of the epitaxial layer 102 and that of the heavily doped region 102c.

The lightly doped region 102d is disposed on the heavily doped region 102c. The lightly doped region 102d may be doped with the first impurities at a concentration of approximately 1×10¹³ atom/cm³ to approximately 1×10¹⁶ atom/cm³. As described above, the lightly doped region 102d contributes to photoelectric conversion. Hence, the lightly doped region 102d should have a sufficient thickness. If the distance between the surface of the epitaxial layer 102 and that of the heavily doped region 102c is excessively large, however, sensitivity to a red wavelength may be excessively increased, and crosstalk between pixels may occur. Therefore, the distance must be controlled by taking the above problems into consideration. In this exemplary embodiment, the distance determines the thickness of the lightly doped region 102d. For example, the thickness of the lightly doped region 102d may be in the range of approximately 1 to 5 μm.

The second impurity distribution region 102b may be doped with the second impurities at a concentration of approximately 1×10¹³ atom/cm³ to approximately 1×10¹⁶ atom/cm³. The second impurity distribution region 102b is disposed at the top of the epitaxial layer 102. That is, a top surface of the second impurity distribution region 102b is the outer surface of the epitaxial layer 102. The second impurity distribution region 102b contributes to an increase in charge collection capacity of the photoelectric converter 110. In the second impurity distribution region 102b, impurities of a conductivity type (the N type) identical to that of impurities doped into the charge collection well 111 are distributed. Therefore, the doping concentration of the charge collection well 111 may be controlled to increase the depth of an electric well. In addition, the volume (depth) of the charge collection well 111 may be increased in order to increase the charge collection capacity. The second impurity distribution region 102b contributes to photoelectric conversion efficiency, together with the lightly doped region 102e of the first impurity distribution region 102a. With this consideration in mind, the thickness of the second impurity distribution region 102b is controlled. More specifically, because the second impurity distribution region 102b contributes to an increase in green sensitivity, it may have an appreciable thickness. An applicable thickness of the second impurity distribution region 102b may be approximately 0.5 to 1.5 μm.

A total thickness of the epitaxial layer 102 and the thickness of each of the heavily doped region 102c, the lightly doped region 102d, and the second impurity distribution region 102b may be easily controlled in an epitaxial growth process. In addition, the concentration of impurities in each region may be easily controlled in the process of growing the epitaxial layer 102. Therefore, thickness and concentration can be accurately controlled to meet the specific design. More specifically, because an additional ion implantation process is not required to form the heavily doped region 102c at the bottom of the epitaxial layer 102, an attack on the epitaxial layer 102 due to the ion implantation process can be reduced, thereby enhancing device reliability.

A transfer gate structure 130 including the transfer gate electrode 132 is formed on the epitaxial layer 102. The transfer gate structure 130 includes a gate insulation film 134 in addition to the transfer gate electrode 132. The gate insulation film 134 may be made of SiO2, SiOn, SiN, Al2O3, Si3N4, GexOyNz, GexSiyOz, or a high dielectric constant (high-k) material film. The high-k material film may be made of HfO2, ZrO2, Al2O3, Ta2O5, hafnium silicate, zircornium silicate, or a combination of the same.

Selectively, the transfer gate structure 130 may further include spacers 138 formed on sidewalls of the transfer gate electrode 132 and the gate insulation film 134. The spacers 138 may be made of SiN.

In the epitaxial layer 102, the charge collection well 111 and the charge detector 120 face each other with the transfer gate electrode 132 therebetween. Furthermore, a threshold voltage control region 136 and an isolation well 108 may be formed in the epitaxial layer 102. Each of the charge collection well 111, the charge detector 120, the threshold voltage control region 136, and the isolation well 108 may be defined by doping different impurities into the epitaxial layer 102. That is, they are distinguished from the adjacent epitaxial layer 102 by types and concentrations of impurities doped therein.

The charge collection well 111 extends from a side of the transfer gate electrode 132 in an outward direction. In addition, the charge collection well 111 may partially overlap the transfer gate electrode 132. The charge collection well 111 may have the second conductivity type (the N type) in order to collect and store photoelectrically converted electric charges in the region between the surface of the epitaxial layer 102 and the surface of the heavily doped region 102c. To have the second conductivity type, the charge collection well 111 is heavily doped with the third impurities. The third impurities doped into the charge collection well 111 may be phosphorous (P) or arsenic (As) like the second impurities doped into the second impurity distribution region 102b. The third impurities are not necessarily identical to the second impurities, however. For example, the second impurities may be phosphorous (P), whereas the third impurities doped into the charge collection well 111 may be arsenic (As).

The charge collection well 111 occupies the second impurity distribution region 102b and the lightly doped region 102d of the first impurity distribution region 102a. Therefore, the first and second impurities, as well as the doped third impurities described above, coexist in the charge collection well 111. In this exemplary embodiment, the third impurities predominate in the charge collection well 111 in terms of concentration. From this point of view, the concentration of the doped third impurities may be approximately 1×10¹⁴ atom/cm³ to approximately 1×10¹⁸ atom/cm³. Therefore, electrical characteristics of the charge collection well 111 are mainly dependent on the concentration of the doped third impurities.

It is not necessary for the third impurities to be evenly doped in the charge collection well 111. The third impurities must be distributed at a sufficiently high concentration in the lightly doped region 102d, however, in which at least the first impurities of the first conductivity type (the P type) are distributed, so that the charge collection well 111 can continue to be of the second conductivity type (the N type) having a sufficient electric potential. That is, the third impurities must be distributed in the lightly doped region 102d at a concentration sufficient to offset the first conductivity type (the P type) of the lightly doped region 102d and turn the entire conductivity type of the lightly doped region 102d into the second conductivity type. Furthermore, the third impurities must be distributed at a concentration enough to have a sufficient electric potential. Because the second impurity distribution region 102b already represents the second conductivity type (the N type) due to the second impurities, however, the third impurities are not necessarily distributed in the second impurity distribution region 102b.

In this regard, the charge collection well 111 includes the first impurity distribution region 102a, as well as a region doped with the third impurities. As a result, the thickness and volume of the charge collection well 111 are increased as compared to when the charge collection well 111 includes the third impurities only. An increase in the volume of the charge collection well 111 is related to an increase in photoelectric storage capacity. That is, as the volume of the charge collection well 111 increases, the collection efficiency of photoelectric charge data is enhanced. In addition, an increase in the thickness of the charge collection well 111 improves green sensitivity.

As the capacity of the charge collection well 111 increases as described above, the concentration of the third impurities doped into the charge collection well 111 may be relatively reduced. If the concentration of the third impurities is relatively reduced, an electric field of a P-N junction between the charge collection well 111 of the second conductivity type (the N type) and its neighboring region of the first conductivity type (the P type) may be reduced. Therefore, a charge trapping phenomenon in a boundary region between them can be reduced. Consequently, electric charges trapped, and thus remaining even if a transfer transistor is turned on, can be reduced, thereby preventing signal distortions or image delays.

A pinning layer 112 is formed on the charge collection well 111. The pinning layer 112 is thinner than the second impurity distribution region 102b and is formed in the surface of the epitaxial layer 102. Therefore, the pinning layer 112 is located within the second impurity distribution region 102b.

The pinning layer 112 forms the photoelectric converter 110, together with the charge collection well 111. The pinning layer 112 prevents the generation of noise by dangling bonds that may be formed on the surface of the epitaxial layer 102. That is, when stimulated by, for example, heat energy, the dangling bonds on the surface of the epitaxial layer 102 easily generate a large number of pairs of electric charges and holes, and the generated electric charges may cause signal noise. Therefore, the pinning layer 112 removes the generated electric charges and prevents the generated from flowing into the charge collection well 111. To this end, the pinning layer 112 may be heavily doped with impurities of the first conductivity type (the P type) at a concentration of, for example, approximately 1×10¹⁷ to 1×10²⁰ atom/cm³. Although a small amount of the second impurities may also be found in the pinning layer 112, because impurities of the first conductivity type (the P type) predominate in the pinning layer 112, the pinning layer 112 represents the first conductivity type (the P type). Although not specifically illustrated in the drawing, the pinning layer 112 may he selectively introduced and may be omitted when necessary.

The charge detector 120 extends from the other side of the transfer gate electrode 132 in the outward direction. That is, the charge detector 120 faces the charge collection well 111 with the transfer gate electrode 132 therebetween.

Like the charge collection well 111, the charge detector 120 is doped with fourth impurities of the second conductivity type (the N type) and occupies the second impurity distribution region 102b and the lightly doped region 102d. The fourth impurities may be identical to the third impurities. In order to allow electric charges collected by the charge collection well 111 to easily move to the charge detector 120, the electric potential may be inclined. To this end, the doping concentration of the charge detector 120 may be higher than that of the charge collection well 111. The doping concentration of the charge detector 120 may be, for example, approximately 1×10¹⁴ atom/cm³ to approximately 1×10¹⁹ atom/cm³.

The threshold voltage control region 136 is interposed between the charge collection well 111 and the charge detector 120 and overlaps the transfer gate electrode 132. The threshold voltage control region 136 is disposed within the second impurity distribution region 102b. In addition, impurities of the first conductivity type (the P type) are doped into the threshold voltage control region 136. A threshold voltage of the transfer transistor is controlled by adjusting a conductivity type and the electric potential according to the concentration of the doped impurities and that of the second impurities. For example, the concentrations of the impurities may be controlled to allow the threshold voltage control region 136 to have the first conductivity type (the P type). Accordingly, the threshold voltage of the transfer transistor may be increased, thereby preventing generation of leakage current.

The threshold voltage control region 136 forms the charge transmitter, together with the transfer gate electrode 132 and the gate insulation film 134. The threshold voltage control region 136 may be omitted when necessary.

The isolation well 108 defines each unit pixel of the image sensor and prevents crosstalk between unit pixels. To this end, the isolation well 108 is heavily doped with impurities of the first conductivity type (the P type) at a concentration of approximately 1×10¹⁵ atom/cm³ to approximately 1×10²² atom/cm³. The isolation well 108 may occupy the second impurity distribution region 102b and the lightly doped region 102d and may be formed deep in the lightly doped region 102d. Furthermore, the isolation well 108 may be formed to the bottom of the lightly doped region 102d and thus contact the heavily doped region 102c or maybe formed to be within the heavily doped region 102c.

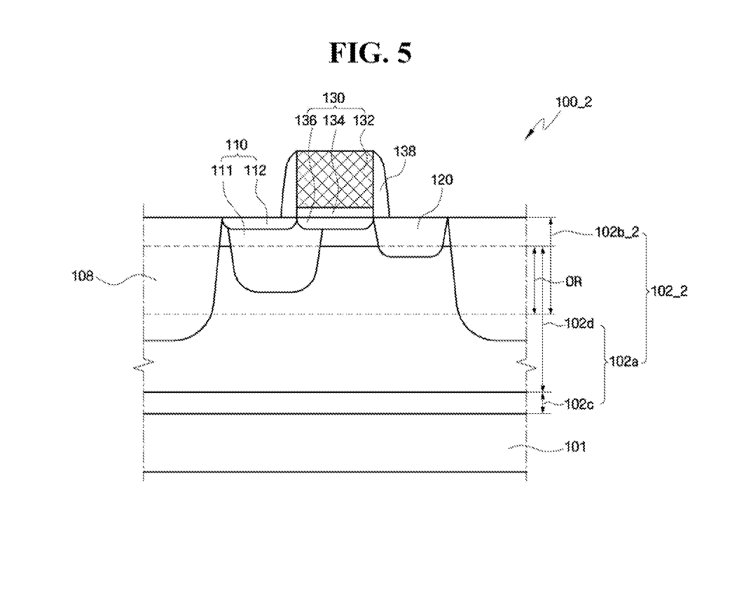

FIG. 5 is a cross-sectional view of an image sensor according to an exemplary embodiment of the present invention. Specifically, FIG. 5 illustrates a unit pixel 100_2 of the image sensor in which a lightly doped region 102d of a first impurity distribution region 102a of an epitaxial layer 102_2 partially overlaps a second impurity distribution region 102b_2, which in FIG. 5 is the region “OR”. That is, referring to FIG. 5, the second impurity distribution region 102b_2 may be extended to and/or down a charge collection well 111. The second impurity distribution region 102b_2 may be extended when the epitaxial layer 102_2 is formed. Alternatively, the second impurity distribution region 102b_2 may be extended by the second impurities that are diffused downward over time and/or in a subsequent process. More specifically, if the second impurities are phosphorous (P) and the third impurities newly doped into the charge collection well 111 are arsenic (As), the second impurities may pass the charge collection well 111 and may be diffused down the charge collection well 111 because the diffusion speed of phosphorous (P) is faster than that of arsenic (As).

If the concentration of the second impurities in a diffusion region OR is not as high as required by the charge collection well 111, the diffusion region OR is not included in the charge collection well 111. The diffusion region OR forms an electric potential slope with respect to the charge collection well 111, however, and it increases mobility of electric charges. In addition, the probability that photoelectrically converted electric charges will be recombined with holes is reduced in the diffusion region OR due to the second impurities of the second conductivity type (the N type). Therefore, collection efficiency of electric charges is enhanced. Furthermore, the diffusion region OR substantially increases the capacity of the charge collection well 111. Since the charge collection well 111 of the second conductivity type (the N type) is surrounded by the diffusion region OR of the second conductivity type (the N type), a P-N junction is not formed on a boundary surface between the charge collection well 111 and the diffusion region OR. Consequently, the charge trapping phenomenon does not occur in this boundary region, which, in turn, prevents signal distortions or image delays.

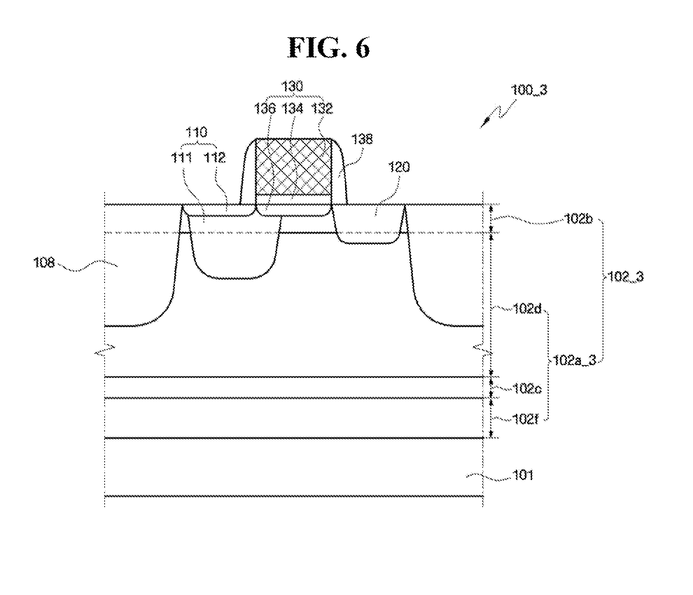

FIG. 6 is a cross-sectional view of an image sensor according to an exemplary embodiment of the present invention. Specifically, FIG. 6 illustrates a unit pixel 100_3 of the image sensor in which a first impurity distribution region 102a_3 of an epitaxial layer 102_3 is divided into three regions. That is, referring to FIG. 6, the epitaxial layer 102_3 includes a first lightly doped region 102f, a heavily doped region 102c, and a second lightly doped region 102d. The heavily doped region 102c and the second lightly doped region 102d are substantially identical to the heavily doped region 102c and the lightly doped region 102d of FIG. 4. The first lightly doped region 102f is interposed between the heavily doped region 102c and a bare substrate 101.

The first lightly doped region 102f and the second lightly doped region 102d may be substantially identical to each other. That is, they may be doped with impurities of the same type, and their concentrations may be within the same range. Thus, it may be understood that the heavily doped region 102c according to this exemplary embodiment of the present embodiment is located in the middle of a rather wide lightly doped region. In the present exemplary embodiment, however, electric charges that are collected as data may also be limited to those generated in a region between a surface of the heavily doped region 102c and that of the epitaxial layer 102_3 thereabove. That is, the second lightly doped region 102d and the second impurity distribution region 102b contribute to photoelectric conversion efficiency.

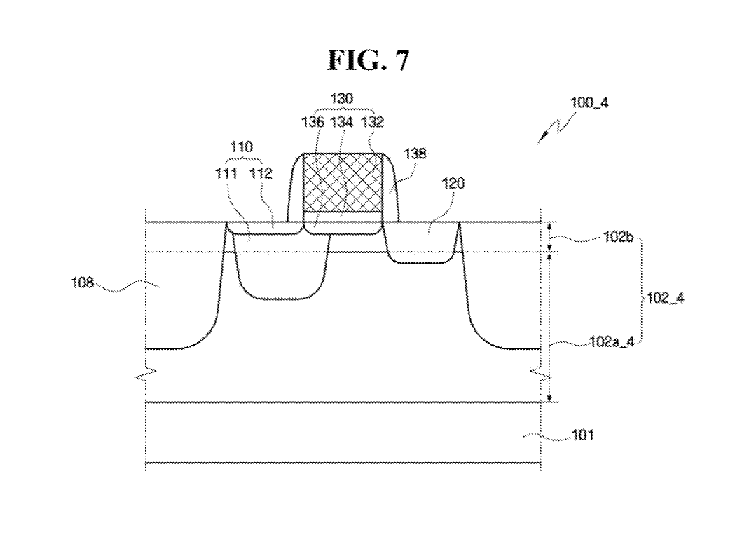

FIG. 7 is a cross-sectional view of an image sensor according to an exemplary embodiment of the present invention. Referring to FIG. 7, in a unit pixel 100_4 of the image sensor according to an exemplary embodiment of the present embodiment, a first impurity distribution region 102a_4 of an epitaxial layer 102_4 does not include a heavily doped region and includes only a lightly doped region. That is, the image sensor according to the present exemplary embodiment of FIG. 7 does not have a deep well. Therefore, in the present embodiment, a bare substrate 101 disposed under the first impurity distribution region 102a_4 is required to be a heavily doped substrate of the first conductivity type (the P type). For example, because the bare substrate 101 does not include a deep well, a substrate of the first conductivity type, which is heavily doped with the first impurities at a concentration of approximately 1×10¹⁴ atom/cm³ to approximately 1×10²² atom/cm³, may be applied as the bare substrate 101.

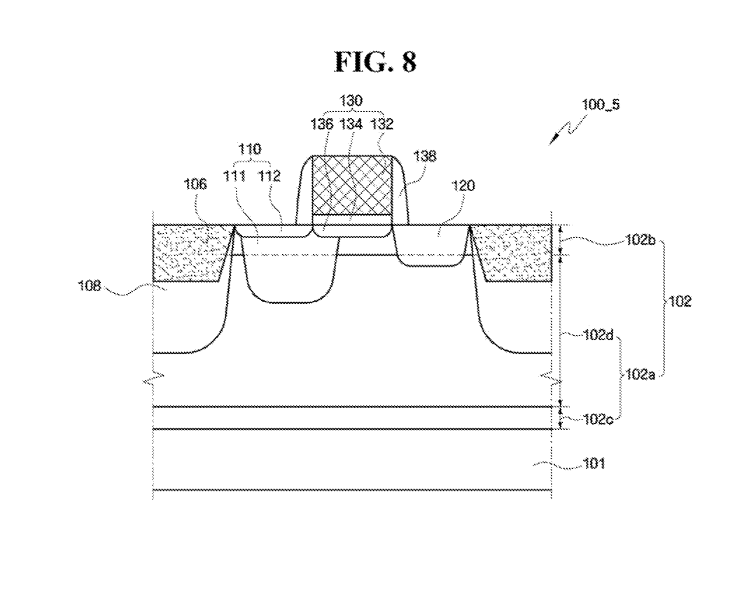

FIG. 8 is a cross-sectional view of an image sensor according to an exemplary embodiment of the present invention. Various examples of device isolation are illustrated in FIG. 8. Device isolation for preventing crosstalk may be achieved using only the isolation well 108 as described above with reference to FIG. 4. Device isolation, however, may also be achieved using both an isolation well 108 and a device isolation film 106, as illustrated in FIG. 8. In another example, the isolation well 108 maybe excluded. That is, device isolation may be achieved using only the device isolation film 106. The device isolation film 106 may be, for example, a local oxidation of silicon (LOCOS) film or a shallow trench isolation (STI) film. The device isolation film 106 may be poor at generating dangling bonds. Because the device isolation film 106 is formed of an insulation film, however, it may exhibit better device isolation characteristics than the isolation well 108. The device isolation film 106 may often be provided to guarantee uniformity of the chemical mechanical polishing (CMP) that is applied to a fabrication process.

If the device isolation film 106 is an STI film, the STI film does not overlap the first impurity distribution region 102a and the second impurity distribution region 102b. That is, because the STI film is formed by partially removing an epitaxial layer 102 and then burying an insulation film, it is no longer the epitaxial layer 102. Thus, it is difficult to expect forming the first and second impurity distribution regions 102a and 102b in the device isolation film 106. If impurities are newly doped into the device isolation film 106 in a subsequent process, however, the device isolation film 106 may be included in the first impurity distribution region 102a and the second impurity distribution region 102b.

The examples described above may be variously combined.

Hereinafter, methods of fabricating image sensors such as those described above will be described. In the following exemplary embodiments for the fabrication method, a description of structures, materials, sizes, concentrations and positions that are identical to, or that can be easily inferred from, the above-described exemplary embodiments for the structure of the image sensor will be omitted or simplified.

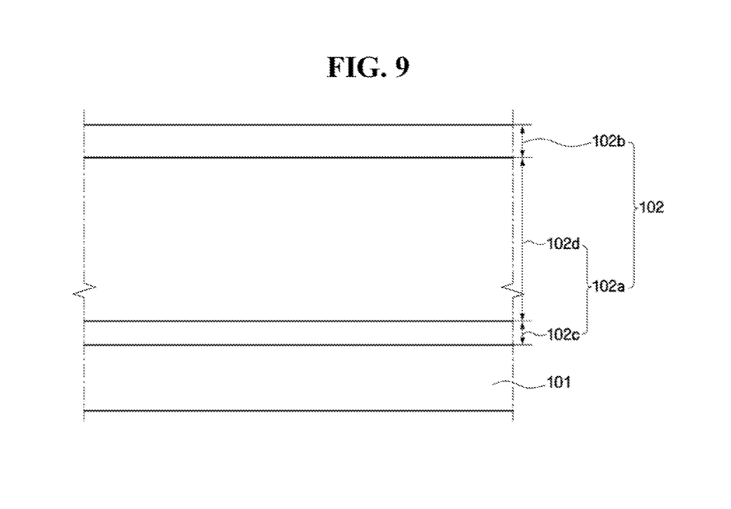

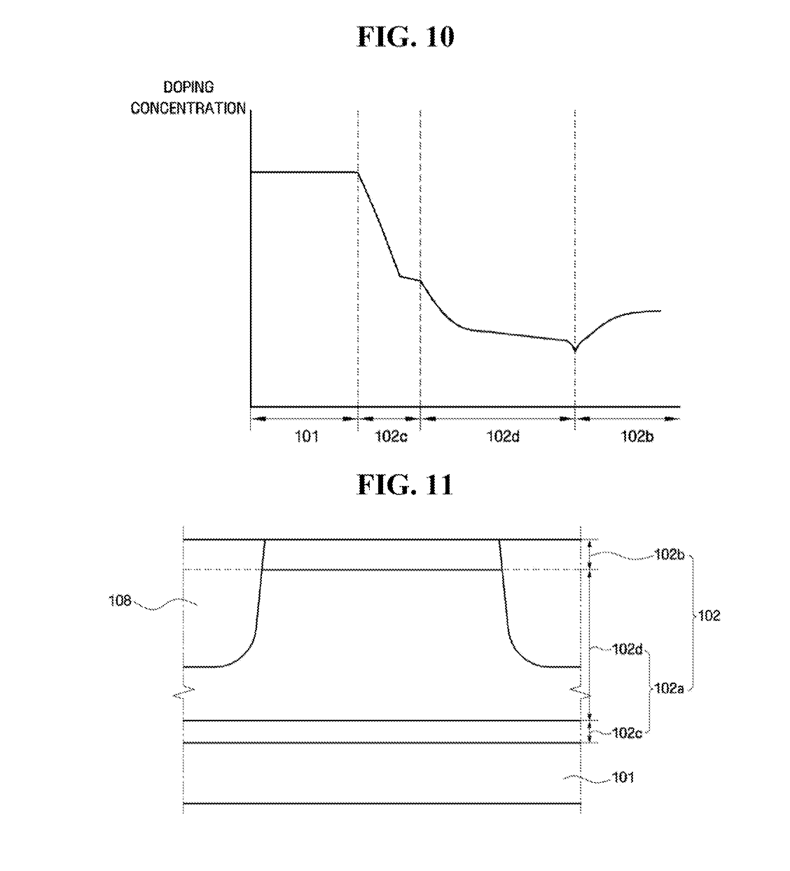

FIGS. 9 and 11 through 16 are cross-sectional views for explaining a method of fabricating an image sensor according to an exemplary embodiment of the present invention. FIG. 10 is a schematic graph of a value representing the relative concentration of impurities doped into each region of the epitaxial substrate.

Referring to FIGS. 9 and 10, the epitaxial substrate including a first impurity distribution region 102a and a second impurity distribution region 102b is provided.

The epitaxial substrate may be formed by epitaxially growing, for example, silicon on a bare substrate 101.

Referring to FIG. 10, the bare substrate 101 shows the highest doping concentration of impurities among each region of the epitaxial substrate. That is, the bare substrate 101 suggested as an example may be a substrate of the first conductivity type (the P type) that is heavily doped with impurities at a concentration of approximately 1×10¹⁴ atom/cm³ to approximately 1×10²² atom/cm³.

Next, an epitaxial growth process is performed by simultaneously supplying a source gas and an impurity gas onto the bare substrate 101. Since a heavily doped region 102c of the first impurity distribution region 102a is disposed at the bottom of an epitaxial layer 102, the epitaxial growth process is performed by supplying a first impurity gas at a high concentration. The concentration of the first impurity gas is controlled within a range that allows the growing epitaxial layer 102 to have first impurities at a concentration of approximately 1×10¹⁴ atom/cm³ to approximately 1×10¹⁹ atom/cm³.

When the heavily doped region 102c grows to a target thickness, the epitaxial growth process is performed by supplying the first impurities at a lower concentration in order to form a lightly doped region 102d. The concentration of the first impurity gas is controlled within a range that allows the growing epitaxial layer 102 to have the first impurities at a concentration of approximately 1×10¹³ atom/cm³ to approximately 1×10¹⁶ atom/cm³.

Next, when the lightly doped region 102d grows to a target thickness, the epitaxial growth process is performed by supplying the source gas and the second impurity gas while stopping the supply of the first impurity gas. The concentration of the second impurity gas is controlled within a range that allows the growing epitaxial layer 102 to have second impurities at a concentration of approximately 1×10¹³ atom/cm³ to approximately 1×10¹⁶ atom/cm³.

When the second impurity distribution region 102b is formed to a target thickness, the epitaxial growth process is finished.

The epitaxial growth process for epitaxially growing the epitaxial layer 102 may exclude an ion doping process. Therefore, the epitaxial layer 102 may be formed without an attack due to the ion implantation process. In addition, because growing the epitaxial layer 102 and doping impurities into the epitaxial layer 102 are performed simultaneously, the concentration of the impurities can be easily and accurately controlled, so as to be close to the design values. Furthermore, the thickness of each region can be freely and accurately controlled. Thus, an electro-potential can be accurately implemented as designed. In particular, it is advantageous for controlling the charge collection capacity of a photoelectric converter.

Referring to FIG. 11, impurity ions of the first conductivity type (the P type) are implanted into the epitaxial layer 102 to form an isolation well 108. In this exemplary embodiment, the doping concentration of the isolation well 108 is controlled to become higher than that of the lightly doped region 102d of the adjacent first impurity distribution region 102a. In addition, doping energy is controlled such that the isolation well 108 can be formed in the second impurity distribution region 102b and formed to a predetermined depth of the lightly doped region 102d of the first impurity distribution region 102a. Although not shown in the drawing, a doping mask, such as photoresist, may be used to form the isolation well 108, and this also applies to the following ion implantation process. Each unit pixel of the image sensor is defined by the isolation well 108 thus formed.

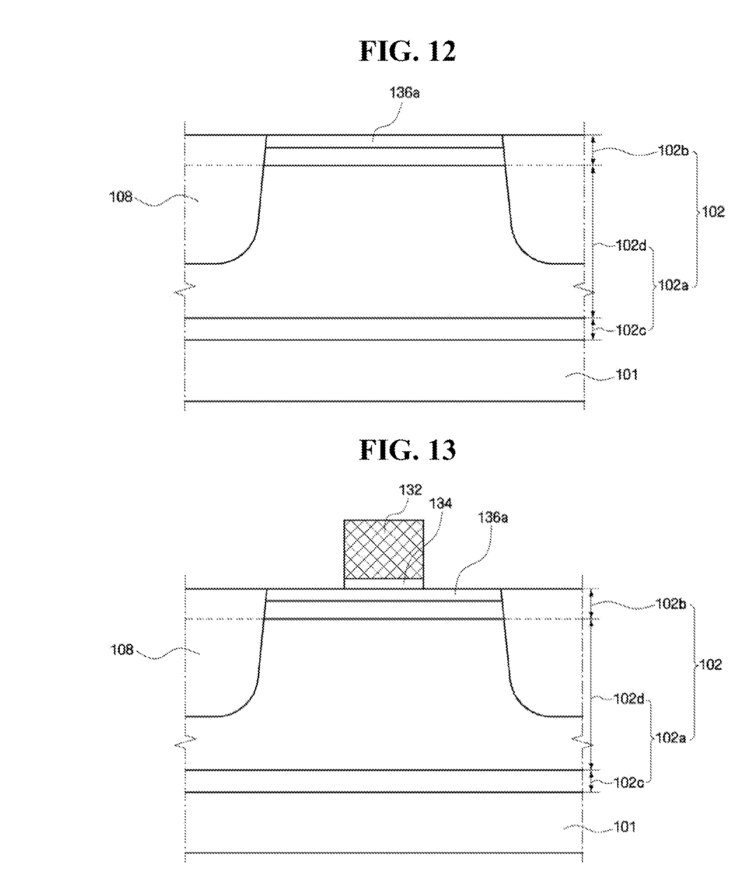

Referring to FIG. 12, impurities of the first conductivity type (the P type) are ion-implanted onto a top surface of the epitaxial layer 102 of each unit pixel defined by the isolation well 108, thereby forming an impurity region 136a for controlling a threshold voltage. In this exemplary embodiment, the impurity region 136a may be formed thin within the second impurity distribution region 102b.

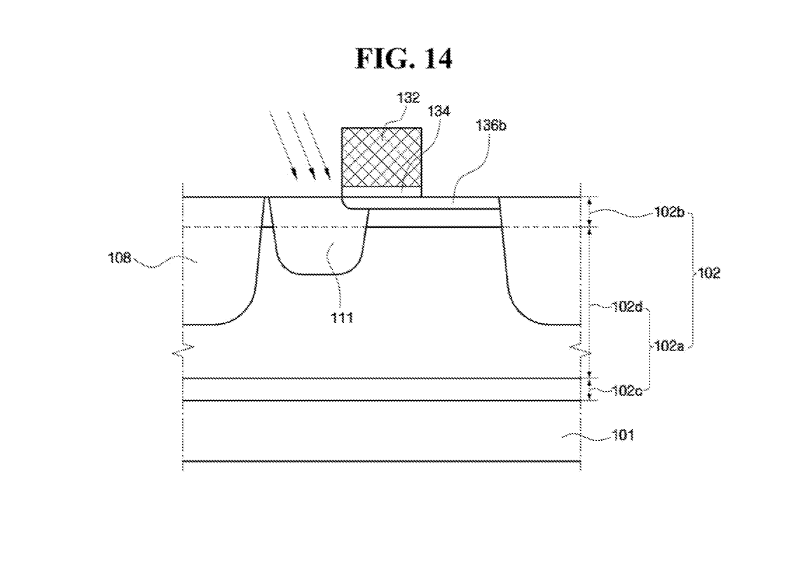

Referring to FIG. 13, a thermal oxidation process, a deposition process and a patterning process known generally in the art to which the present invention pertains, are performed on the impurity region 136a. Consequently, a gate insulation film 134 and a transfer gate electrode 132 are formed. Referring to FIG. 14, third impurities are ion-implanted into a side of the transfer gate electrode 132 to form a charge collection well 111. In this case, the third impurities may be ion-implanted at a predetermined angle, for example, a tilt angle of approximately 10 degrees, as shown by the arrows in FIG. 14, so that the charge collection well 111 can partially overlap the transfer gate electrode 132 in an inward direction of the transfer gate electrode 132. After the third impurities are ion-implanted, a portion of the impurity region 136a disposed at a side of the transfer gate electrode 132 may substantially disappear and may be included in the charge collection well 111 and the impurity region 136b remains. When a pinning layer 112, which will be described hereinbelow, is formed, however, the impurity region 136a may be excluded from the charge collection well 111.

The third impurities are ion-implanted into not only the second impurity distribution region 102b but also into part of the lightly doped region 102d. Therefore, the first through third impurities coexist in the charge collection well 111.

If thermal treatment processes are performed during the ion implantation process or a subsequent process, the implanted ions are diffused, thereby increasing the volume of each region. Accordingly, the volume of the charge collection well 111 is increased, which, in turn, increases the photoelectric conversion capacity. Furthermore, if the second impurities are phosphorous (P) and the third impurities are arsenic (As), the second impurities may be diffused down the charge collection well 111, because the diffusion speed of phosphorous (P) is faster than that of arsenic (As), as described above with reference to FIG. 5. As described above, the extension of the second impurity distribution region 102b contributes to an increase in the photoelectric conversion capacity and efficiency and, in particular an increase in green sensitivity.

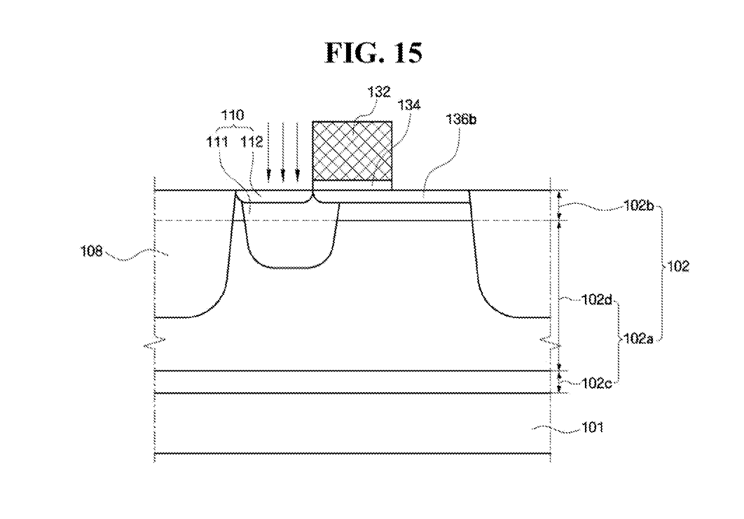

Referring to FIG. 15, impurities of the first conductivity type (the P type) are heavily ion-implanted into a surface of the charge collection well 111 to form the pinning layer 112.

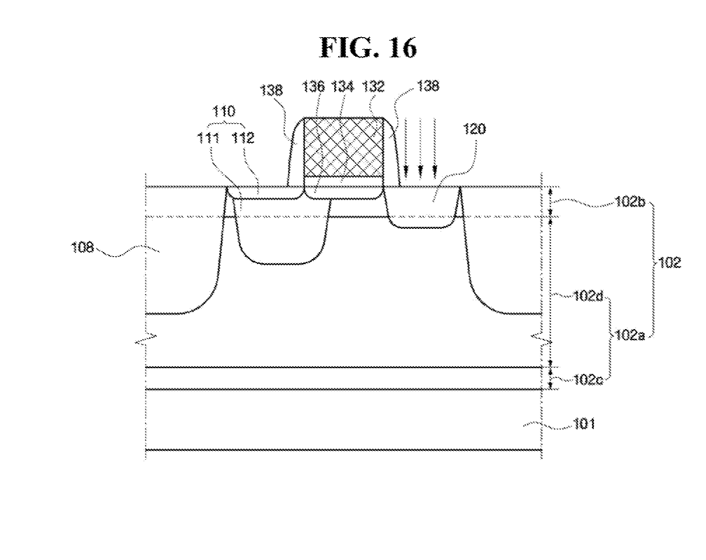

Referring to FIG. 16, fourth impurities are heavily ion-implanted into a location facing the charge collection well 111 with the transfer gate electrode 132 therebetween. Like the charge collection well 111, the charge detector 120 may occupy the second impurity distribution region 102b and the lightly doped region 102d. A threshold voltage control region 136 and an isolation well maybe formed in the epitaxial layer 102.

Next, a gate nitride film is deposited on a whole surface of the resultant structure of FIG. 16 and etched back to form spacers 138. Consequently, the image sensor identical to that of FIG. 4 is completed. The spacers 138 may also be formed in a previous process. In this case, it is seen that the position and alignment of each region changes accordingly.

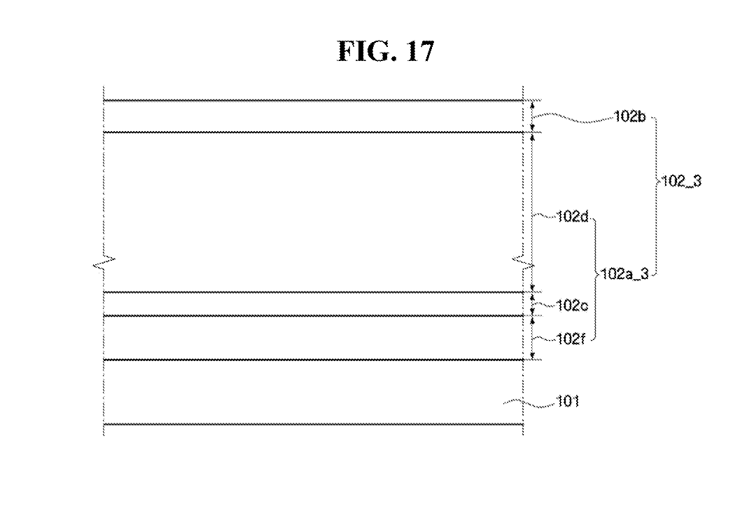

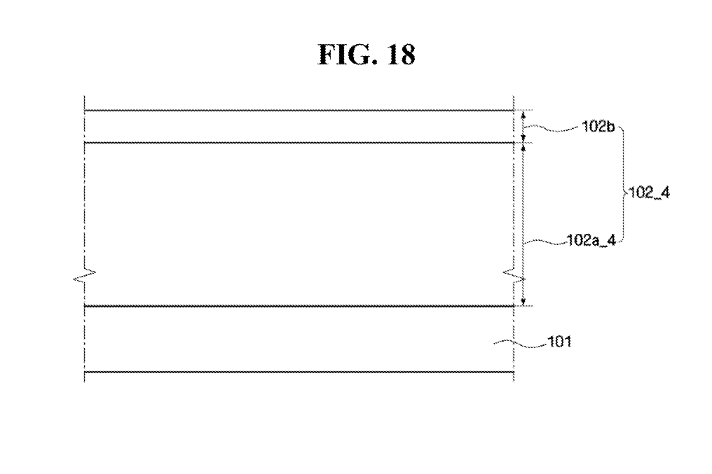

FIGS. 17 and 18 are cross-sectional views of epitaxial substrates used to fabricate the image sensors of FIGS. 6 and 7, respectively. The structures of the epitaxial layers 102_3 and 102_4 provided to fabricate the image sensors of FIGS. 6 and 7 are different from the structure of the epitaxial layer 102 of FIG. 9.

That is, in order to fabricate the image sensor of FIG. 6, the epitaxial substrate, in which the first impurity distribution region 102a_3 of the epitaxial layer 102 __3 is divided into three regions, that is, the first lightly doped region 102f, the heavily doped region 102c and the second lightly doped region 102d, is provided as illustrated in FIG. 17. In order to fabricate the image sensor of FIG. 7, the epitaxial substrate, in which the first impurity distribution region 102a_4 of the epitaxial layer 102_4 does not include a heavily doped region and a lightly doped region is formed immediately on the bare substrate 101, is provided as illustrated in FIG. 18. It is apparent to those of ordinary skill in the art that each region of each epitaxial substrate is epitaxially grown by controlling the concentration of the first impurities. Subsequent processes are substantially identical to those described above with reference to FIGS. 11 through 16, and thus a detailed description thereof will be omitted.

In order to fabricate the image sensor of FIG. 8, however, a process for forming a device isolation film may be performed additionally in the processing process of FIG. 11. The device isolation film may be performed in, for example, a LOCOS process or an STI process. The process for forming the device isolation film may be performed before or after the formation of an isolation well.

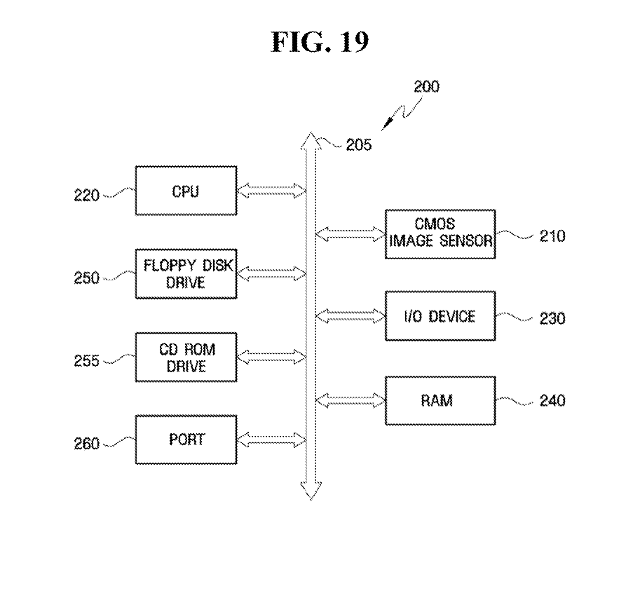

Hereinafter, a processor-based system including an image sensor such as those described above will be disclosed. FIG. 19 is a schematic diagram illustrating a processor-based system 200 including a CMOS image sensor 210 according to an exemplary embodiment of the present invention.

Referring to FIG. 19, the processor-based system 200 processes an output image of the CMOS image sensor 210. The processor-based system 200 may be, but is not limited to, a computer system, a camera system, a scanner, a mechanized clock system, a navigation system, a videophone, a supervision system, an automatic focus system, a tracking system, a motion detection system, or an image stabilization system.

The processor-based system 200 may include a central processing unit (CPU), for example, a microprocessor, 220 that may communicate with an input/output device 230 via a bus 205. The CMOS image sensor 210 may communicate with the processor-based system 200 via the bus 205 or any other telecommunication link. The processor-based system 200 may further include a random access memory (RAM) 240, a floppy disk drive 250 and/or a CD ROM drive 255, and a port 260, all of which may communicate with the CPU 220 via the bus 205. The port 260 may couple a video card, a sound card, a memory card, or a universal serial bus (USB) device to the processor-based system 200 or may perform data communication with other systems. The CMOS image sensor 210 may be integrated with the CPU 220, or although not shown with a digital signal processor (DSP), a microprocessor, a memory, or the like. The CMOS image sensor 210 may also be integrated onto a chip other than the above processors.

An image sensor according to exemplary embodiments of the present invention includes a plurality of regions that have different concentrations of impurities and that are formed in an epitaxial growth process. Therefore, the thickness of each region can be freely determined, and the thickness and impurity concentration thereof can be accurately controlled as designed. Accordingly, sufficient photoelectric conversion capacity can be secured, and an attack on devices due to an ion implantation process can be prevented, thereby improving device reliability.

In addition, because the depth of a charge collection well in the image sensor is substantially increased, charge collection efficiency is enhanced, and green sensitivity can be improved without increasing red sensitivity.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. An image sensor comprising:
a bare substrate;
an epitaxial layer disposed on the bare substrate and comprising a first impurity distribution region of a first conductivity type and a second impurity distribution region of a second conductivity type that is formed on the first impurity distribution region; and
a charge collection well formed within the epitaxial layer and at least partially doped with third impurities of the second conductivity type,
wherein the charge collection well occupies the first impurity distribution region and the second impurity distribution region and represents the second conductivity type as a whole.

2. The image sensor of claim 1, wherein the first conductivity type is a P type, and the second conductivity type is an N type.

3. The image sensor of claim 2, wherein the first impurity distribution region comprises a heavily doped region and a lightly doped region formed on the heavily doped region, and the charge collection well occupies the lightly doped region of the first impurity distribution region.

4. The image sensor of claim 3, wherein the heavily doped region is doped with first impurities at a concentration of 1×10¹⁴ atom/cm³ to 1×10¹⁹ atom/cm³, the lightly doped region is doped with the first impurities at a concentration of 1×10¹³ atom/cm³ to 1×10¹⁶ atom/cm³, and the second impurity distribution region is doped with second impurities at a concentration of 1×10¹³ atom/cm³ to 1×10¹⁶ atom/cm³.

5. The image sensor of claim 4, wherein the bare substrate is a substrate of the first conductivity type that has a concentration of 1×10¹⁴ atom/cm³ to 1×10²² atom/cm³.

6. The image sensor of claim 4, wherein a doping concentration of the third impurities is 1×10¹⁴ atom/cm³ to 1×10¹⁸ atom/cm³.

7. The image sensor of claim 3, wherein the second impurity distribution region partially overlaps the lightly doped region.

8. The image sensor of claim 7, wherein the second impurity distribution region extends down the charge collection well.

9. The image sensor of claim 8, wherein the second impurities are phosphorous (P), and the third impurities are arsenic (As).

10. The image sensor of claim 3, wherein a thickness of the lightly doped region is in a range of 1 to 5 μm, and a thickness of the second impurity distribution region is in a range of 0.5 to 1.5 μm.

11. The image sensor of claim 2, wherein the first impurity distribution region comprises a first lightly doped region, a heavily doped region, and a second lightly doped region formed sequentially.

12. The image sensor of claim 2, wherein the first impurity distribution region is comprised of a lightly doped region.

13. The image sensor of claim 1, wherein the first impurity distribution region is doped with the first impurities at a concentration of 1×10¹¹ atom/cm³ or greater, and the second impurity distribution region is doped with the second impurities at a concentration of 1×10¹¹ atom/cm³ or greater.

14. A method of fabricating an image sensor, the method comprising:
providing an epitaxial substrate for an image sensor, the epitaxial substrate comprising a bare substrate and an epitaxial layer disposed on the bare substrate and comprising a first impurity distribution region of a first conductivity type and a second impurity distribution region of a second conductivity type formed on the first impurity distribution region; and
forming a charge collection well, which is at least partially ion-doped with third impurities of the second conductivity type, within the epitaxial layer,
wherein the charge collection well occupies the first impurity distribution region and the second impurity distribution region and represents the second conductivity type as a whole.

15. The method of claim 14, wherein the first conductivity type is a P type, and the second conductivity type is an N type.

16. The method of claim 15, wherein the first impurity distribution region comprises a heavily doped region and a lightly doped region formed on the heavily doped region, and the charge collection well occupies the lightly doped region of the first impurity distribution region.

17. The method of claim 16, wherein the heavily doped region is doped with first impurities at a concentration of 1×10¹⁴ atom/cm³ to 1×10¹⁹ atom/cm³, the lightly doped region is doped with the first impurities at a concentration of 1×10¹³ atom/cm³ to 1×10¹⁶ atom/cm³, and the second impurity distribution region is doped with second impurities at a concentration of 1×10¹³ atom/cm³ to 1×10¹⁶ atom/cm³.

18. The method of claim 17, wherein the bare substrate is a substrate of the first conductivity type that has a concentration of 1×10¹⁴ atom/cm³ to 1×10²² atom/cm³.

19. The method of claim 17, wherein a doping concentration of the third impurities is 1×10¹⁴ atom/cm³ to 1×10¹⁸ atom/cm³.

20. The method of claim 16, wherein the second impurities are phosphorous (P), and the third impurities are arsenic (As).

21. An epitaxial substrate for an image sensor, the epitaxial substrate comprising:
a bare substrate; and
an epitaxial layer disposed on the bare substrate and comprising a first impurity distribution region of a first conductivity type, which is formed on the bare substrate, and a second impurity distribution region of a second conductivity type, which is formed on the first impurity distribution region.

22. The substrate of claim 21, wherein the first conductivity type is a P type, and the second conductivity type is an N type.

23. The substrate of claim 22, wherein the first impurity distribution region comprises a heavily doped region and a lightly doped region formed on the heavily doped region.

24. The substrate of claim 23, wherein the heavily doped region is doped with first impurities at a concentration of 1×10¹⁴ atom/cm³ to 1×10¹⁹ atom/cm³, the lightly doped region is doped with the first impurities at a concentration of 1×10¹³ atom/cm³ to 1×10¹⁶ atom/cm³, and the second impurity distribution region is doped with second impurities at a concentration of 1×10¹³ atom/cm³ to 1×10¹⁶ atom/cm³.

25. The substrate of claim 24, wherein the bare substrate is a substrate of the first conductivity type that has a concentration of 1×10¹⁴ atom/cm³ to 1×10²² atom/cm³.
